(19) United States
(12) Patent Application Publication
(10) Pub. No.: US 2026/0299292 A1
(43) Pub. Date: Oct. 1, 2026

(54) OPTICAL WAVEGUIDE DEVICE AND AR DISPLAY APPARATUS

(71) Applicants: Beijing BOE Technology Development Co., Ltd., Beijing (CN); BOE Technology Group Co., Ltd., Beijing (CN)

(72) Inventors: Kang GUO, Beijing (CN); Dongliang ZHANG, Beijing (CN); Hong CHEN, Beijing (CN); Mengya SONG, Beijing (CN); Xin GU, Beijing (CN)

(21) Appl. No.: 19/479,315

(22) PCT Filed: Mar. 20, 2024
(86) PCT No.: PCT/CN2024/082611

§ 371 Date: Oct. 27, 2025

(30) Foreign Application Priority Data
Apr. 28, 2023 (CN) 202310486024.1

(51) Int. Cl. G02B 27/01; G02B 5/18; G02B 27/00; G02B 27/42

(52) U.S. Cl. CPC G02B 27/0101; G02B 5/1819; G02B 5/1842; G02B 5/1861; G02B 5/1866; G02B 27/0081; G02B 27/4205; G02B 27/4272

(57) ABSTRACT

An optical waveguide device and an AR display apparatus. The optical waveguide device is applied to an AR display apparatus, and the optical waveguide device comprises: an optical waveguide plate (11), and a coupling-in grating (12), at least two folding gratings (13) and a coupling-out grating (14), which are arranged on the optical waveguide plate (11), wherein a first folding grating (231) is configured to receive +1-order diffracted light from the optical waveguide plate (11), a second folding grating (232) is configured to receive −1-order diffracted light from the optical waveguide plate (11), and the coupling-out grating (14) is configured to receive the +1-order diffracted light from the first folding grating (231) and the −1-order diffracted light from the second folding grating (232), and to emit the +1-order diffracted light and the −1-order diffracted light.

### CROSS-REFERENCE TO RELATED APPLICATIONS

The present application is a U.S. National Phase Entry of International Application No. PCT/CN2024/082611 having an international filing date of Mar. 20, 2024, which claims the priority of the Chinese patent application No. 202310486024.1, filed to the CNIPA on Apr. 28, 2023 and entitled “Optical Waveguide Device and AR Display Apparatus”. Contents of the above-identified applications are incorporated into the present application by reference.

### TECHNICAL FIELD

Embodiments of the present disclosure relate to, but are not limited to, the field of display technologies, and particularly relate to a display waveguide device and AR display apparatus.

### BACKGROUND

With the development of society and the continuous innovation of science and technology, augmented reality (AR) has gradually entered people's lives. An optical waveguide technology is an indispensable step in AR augmented reality. It uses a flat optical waveguide sheet with diffraction grating to transmit and expand an image emitted by a light source assembly to the human eye, so that users can observe the virtual image projected by the light source assembly and superimposed onto the world while seeing the real world.

### SUMMARY

The following is a summary of subject matter described in the present disclosure in detail. This summary is not intended to limit the protection scope of claims.

In a first aspect, an embodiment of the present disclosure provides an optical waveguide device for an AR display apparatus. The optical waveguide device includes: an optical waveguide plate, and an in-coupling grating, at least two turning gratings and an out-coupling grating arranged on the optical waveguide plate. The in-coupling grating is configured to in-couple incident light into the optical waveguide plate and to form +1-order diffracted light and −1-order diffracted light in the optical waveguide plate.

The at least two turning gratings include a first turning grating and a second turning grating. The first turning grating is configured to receive the +1-order diffracted light from the optical waveguide plate and to propagate the +1-order diffracted light toward the out-coupling grating. The second turning grating is configured to receive the −1-order diffracted light from the optical waveguide plate and to propagate the −1-order diffracted light toward the out-coupling grating.

The out-coupling grating is configured to receive the +1-order diffracted light from the first turning grating and the −1-order diffracted light from the second turning grating and to emit the +1-order diffracted light and the −1-order diffracted light.

In an exemplary implementation, the first turning grating, the second turning grating, and the in-coupling grating are all located on one side of the out-coupling grating in a first direction, and the first turning grating and the second turning grating are located on two opposite sides of the in-coupling grating in a second direction. The first direction intersects the second direction, and the first direction and the second direction are both parallel to the optical waveguide plate.

In an exemplary implementation, a ratio of a sum of areas of orthographic projections of the at least two turning gratings on the optical waveguide plate to an area of an orthographic projection of the out-coupling grating on the optical waveguide plate is from 1:10 to 2:1.

In an exemplary implementation, the in-coupling grating forms the +1-order diffracted light and the −1-order diffracted light with the same diffraction efficiency.

In an exemplary implementation, the in-coupling grating is a one-dimensional grating, the in-coupling grating includes a plurality of first grating structures that are periodically arranged, and a first grating structure of the plurality of first grating structures is in a shape of an elongated strip.

In an exemplary implementation, the in-coupling grating includes at least one of a blazed grating, a tilted grating, and a rectangular grating.

In an exemplary implementation, a transparent dielectric layer is provided on a surface of the first grating structure of the in-coupling grating, and the transparent dielectric layer has a different refractive index from the first grating structure.

In an exemplary implementation, a material of the first grating structure has a refractive index of 1.5 to 2.2. A material of the transparent dielectric layer has a refractive index of 1.5 to 3.0.

In an exemplary implementation, the material of the first grating structure includes a polymer or an inorganic material.

In an exemplary implementation, a material of the transparent dielectric layer is an inorganic material.

In an exemplary implementation, a period of the in-coupling grating is from 250 nanometers to 450 nanometers; and/or the in-coupling grating has a duty cycle of 0.2 to 0.8; and/or a height of the first grating structure of the in-coupling grating is from 50 nanometers to 500 nanometers.

In an exemplary implementation, the in-coupling grating is a blazed grating, a cross section of the first grating structure of the in-coupling grating is triangular in a direction perpendicular to the optical waveguide plate, and an internal angle of the first grating structure is from 30 degrees to 90 degrees.

In an exemplary implementation, the turning grating is a one-dimensional grating, and the turning grating includes a plurality of second grating structures that are periodically arranged, and the second grating structure is in a shape of an elongated strip.

In an exemplary implementation, the turning grating includes at least one of a blazed grating, a tilted grating, and a rectangular grating.

In an exemplary implementation, a reflective layer is provided on a surface of the second grating structure of the turning grating, and the reflective layer has a different refractive index from the second grating structure.

In an exemplary implementation, a material of the reflective layer is a metal or an alloy.

In an exemplary implementation, the reflective layer has a refractive index of 1.5 to 3.

In an exemplary implementation, a step size of light transmission of the turning grating is from 1 mm to 2 mm.

In an exemplary implementation, a material of the second grating structure has a refractive index of 1.5 to 2.2.

In an exemplary implementation, a material of the second grating structure includes a polymer or an inorganic material.

In an exemplary implementation, a period of the turning grating is from 150 nanometers to 450 nanometers; and/or the turning grating has a duty cycle of 0.2 to 0.8; and/or a height of the second grating structure of the turning grating is from 50 nanometers to 500 nanometers.

In an exemplary implementation, the turning grating is a blazed grating, a cross section of the second grating structure of the turning grating is triangular in a direction perpendicular to the optical waveguide plate, and an internal angle of the second grating structure is from 30 degrees to 90 degrees.

In an exemplary implementation, the out-coupling grating is a two-dimensional grating, the out-coupling grating includes a plurality of third grating structures that are periodically arranged, and a third grating structure of the plurality of third grating structures is in a cylinder shape.

In an exemplary implementation, an orthographic projection of the third grating structure on the optical waveguide plate includes at least one of circle, triangle, rectangle, parallelogram, and diamond shape.

In an exemplary implementation, a central axis of the third grating structure is perpendicular to the optical waveguide plate.

In an exemplary implementation, a period of the out-coupling grating is from 250 nanometers to 450 nanometers; and/or the out-coupling grating has a duty cycle of 0.1 to 0.9; and/or a height of the third grating structure of the out-coupling grating is from 50 nanometers to 500 nanometers.

In an exemplary implementation, a material of the third grating structure includes a polymer or an inorganic material.

In an exemplary implementation, a material of the third grating structure has a refractive index of 1.5 to 2.2.

In an exemplary implementation, at least some of the third grating structures of the out-coupling grating have different shapes.

In an exemplary implementation, at least some of the third grating structures of the out-coupling grating have different sizes.

In an exemplary implementation, at least some of the third grating structures of the out-coupling grating gradually get bigger along a direction parallel to the optical waveguide plate.

In an exemplary implementation, an area of an orthographic projection of the out-coupling grating on the optical waveguide plate is greater than or equal to 20 square millimeters.

In an exemplary implementation, the first turning grating is further configured to perform pupil expansion of the +1-order diffracted light in a third direction; and/or the second turning grating is further configured to perform pupil expansion of the −1-order diffracted light in the third direction.

In an exemplary implementation, the out-coupling grating is a one-dimensional grating, the out-coupling grating includes a plurality of fourth grating structures that are periodically arranged, and the fourth grating structure is in a shape of an elongated strip. The out-coupling grating is further configured to perform pupil expansion of the received +1-order diffracted light and the received −1-order diffracted light in a fourth direction, and the third direction intersects the fourth direction.

In an exemplary implementation, the out-coupling grating includes at least one of a blazed grating, a tilted grating, and a rectangular grating.

In an exemplary implementation, a material of the fourth grating structure has a refractive index of 1.5 to 2.2.

In an exemplary implementation, the material of the fourth grating structure includes a polymer or an inorganic material.

In an exemplary implementation, a period of the out-coupling grating is from 250 nanometers to 450 nanometers; and/or the out-coupling grating has a duty cycle of 0.2 to 0.8; and/or a height of the fourth grating structure of the out-coupling grating is from 50 nanometers to 500 nanometers.

In an exemplary implementation, the out-coupling grating is a blazed grating, a cross section of the fourth grating structure of the out-coupling grating is triangular in a direction perpendicular to the optical waveguide plate, and an internal angle of the fourth grating structure is from 30 degrees to 90 degrees.

In an exemplary implementation, at least one of the in-coupling grating, the at least two turning gratings, and the out-coupling grating is made of the same material as the optical waveguide plate, and forms an integral structure with the optical waveguide plate.

In an exemplary implementation, a material of the optical waveguide plate includes a polymer or an inorganic material.

In an exemplary implementation, a material of the optical waveguide plate has a refractive index of 1.5 to 2.2.

In a second aspect, an embodiment of the present disclosure further provides an AR display apparatus, including the optical waveguide device described in any one of above embodiments.

In a third aspect, an embodiment of the present disclosure further provides a preparation method of an optical waveguide device, including: providing an optical waveguide plate; and forming an in-coupling grating, at least two turning gratings and an out-coupling grating on the optical waveguide plate.

The in-coupling grating is configured to in-couple incident light into the light waveguide plate and to form +1-order diffracted light and −1-order diffracted light in the light waveguide plate. The at least two turning gratings include a first turning grating and a second turning grating, the first turning grating is configured to receive the +1-order diffracted light from the optical waveguide plate and to propagate the +1-order diffracted light toward the out-coupling grating. The second turning grating is configured to receive the −1-order diffracted light from the optical waveguide plate and to propagate the −1-order diffracted light toward the out-coupling grating. The out-coupling grating is configured to receive +1-order diffracted light from the first turning grating and −1-order diffracted light from the second turning grating and to emit the +1-order diffracted light and the −1-order diffracted light.

In an exemplary implementation, an in-coupling grating, at least two turning gratings, and an out-coupling grating are formed on the optical waveguide plate by using a nanoimprinting process.

In an exemplary implementation, forming an in-coupling grating, at least two turning gratings, and an out-coupling grating on the optical waveguide plate by using a nanoimprinting process, including: forming an imprinting adhesive layer on the optical waveguide plate; imprinting the imprinting adhesive layer with a mother template having an in-coupling grating pattern, a turning grating pattern and an out-coupling grating pattern by using a nanoimprinting process, so that the imprinting adhesive layer forms a first grating structure, a second grating structure and a third grating structure; and forming the first grating structure into an in-coupling grating, forming the second grating structure into a turning grating, and forming the third grating structure into an out-coupling grating.

In an exemplary implementation, a transparent dielectric layer is formed on the first grating structure such that the first grating structure and the transparent dielectric layer form an in-coupling grating; and/or a reflective layer is formed on the second grating structure, such that the second grating structure and the reflective layer form a turning grating.

In an exemplary implementation, the transparent dielectric layer is made of an inorganic material and the reflective layer is made of a metal or alloy.

In an exemplary implementation, an imprinting adhesive layer is imprinted with a mother template having an in-coupling grating pattern, a turning grating pattern and an out-coupling grating pattern by using a nanoimprinting process, so that the imprinting adhesive layer forms a first grating structure pattern, a second grating structure pattern and a third grating structure pattern. Subsequently, the imprinting adhesive layer and the optical waveguide plate are etched, the first grating structure pattern, the second grating structure pattern and the third grating structure pattern of the imprinting adhesive layer are replicated onto the optical waveguide plate, and the first grating structure, the second grating structure and the third grating structure are formed by partial etching of the optical waveguide plate.

In an exemplary implementation, the first grating structure, the second grating structure, and the third grating structure are made of the same material as the optical waveguide plate, and the first grating structure, the second grating structure, and the third grating structure form an integrated structure with the optical waveguide plate.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present application and constitute a part of the specification, and are used to explain the technical solutions of the present application together with embodiments of the present application, and do not constitute limitations on the technical solutions of the present application.

FIG. 1 is a schematic diagram of a structure of an optical waveguide device according to the related art;

FIG. 2 is a first schematic diagram of a structure of an optical waveguide device according to an embodiment of the present disclosure;

FIG. 3 is a schematic diagram of a planar structure of optical path propagation of an optical waveguide device according to an embodiment of the present disclosure;

FIG. 4 is a schematic diagram of a cross-sectional structure of optical path propagation of an optical waveguide device according to an embodiment of the present disclosure;

FIG. 5 is a first schematic diagram of a cross-sectional structure of an in-coupling grating in an optical waveguide device according to an embodiment of the present disclosure;

FIG. 6 is a schematic diagram of a planar structure of an in-coupling grating in an optical waveguide device according to an embodiment of the present disclosure;

FIG. 7 is a second schematic diagram of a cross-sectional structure of an in-coupling grating in an optical waveguide device according to an embodiment of the present disclosure;

FIG. 8 is a simulation graph of an in-coupling grating in an optical waveguide device according to an embodiment of the present disclosure;

FIG. 9 is a schematic diagram of a cross-sectional structure of a turning grating in an optical waveguide device according to an embodiment of the present disclosure;

FIG. 10 is a schematic diagram of a planar structure of a turning grating in an optical waveguide device according to an embodiment of the present disclosure;

FIG. 11 is a simulation graph of a turning grating in an optical waveguide device according to an embodiment of the present disclosure;

FIG. 12 is a first schematic diagram of a cross-sectional structure of an out-coupling grating in an optical waveguide device according to an embodiment of the present disclosure;

FIG. 13 is a schematic diagram of a planar structure of an out-coupling grating in an optical waveguide device according to an embodiment of the present disclosure;

FIG. 14 is a first schematic diagram of a structure of an optical waveguide device according to an embodiment of the present disclosure;

FIG. 15 is a second schematic diagram of a cross-sectional structure of an out-coupling grating in an optical waveguide device according to an embodiment of the present disclosure;

FIG. 16 is a first schematic diagram of a preparation process of an optical waveguide device according to an embodiment of the present disclosure;

FIG. 17 is a second schematic diagram of a preparation process of an optical waveguide device according to an embodiment of the present disclosure; and

FIG. 18 is a third schematic diagram of a preparation process of an optical waveguide device according to an embodiment of the present disclosure.

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the accompanying drawings, a size of each constituent element, a thickness of a layer, or a region may be exaggerated sometimes for clarity. Therefore, one mode of the present disclosure is not necessarily limited to the size, and a shape and a size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third” and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first pole may be a drain electrode, and a second pole may be a source electrode. Or, the first pole may be a source electrode, and the second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10°and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

In the present disclosure, “about” means that a boundary is not defined so strictly and numerical values within process and measurement error ranges are allowed.

An AR display apparatus based on optical waveguide technology is generally composed of a microdisplay, a collimating eyepiece group, an optical waveguide plate, an in-coupling grating, a turning grating, and an out-coupling grating, and the in-coupling grating, the turning grating and the out-coupling grating are arranged on the same light-transmitting optical waveguide plate. The basic principle of the AR display apparatus is that the microdisplay outputs the required virtual image information, and the collimating eyepiece group plays a collimating role on the virtual image information, transforming the light at each field of view angle into parallel light. Through the in-coupling grating on the optical waveguide plate, the propagation direction of the light is altered to enter the optical waveguide plate. The parallel light at each field of view angle is totally reflected in the optical waveguide plate, propagates along the optical waveguide plate to reach the turning grating, and then reaches the out-coupling grating from the turning grating. The out-coupling grating changes the propagation direction of the light, preventing the light from undergoing total reflection in the optical waveguide plate, and allowing the light to emit from the optical waveguide plate. The beam expands along the propagation direction, and goes into eyes of observers after out-coupling from the optical waveguide plate, achieving the purpose of pupil expansion. At present, AR display apparatuses have problems such as low light efficiency. Generally, the light efficiency of optical modules based on diffraction principles, such as volume holographic gratings or surface relief gratings, is generally less than 5%.

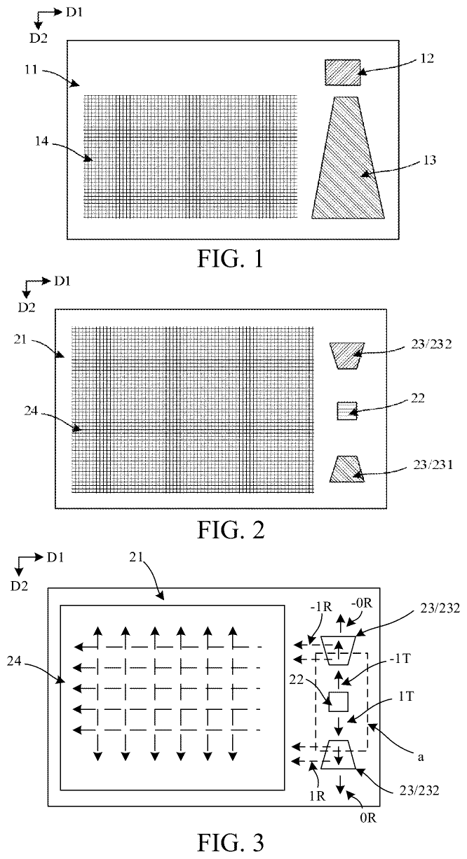

FIG. 1 is a schematic diagram of a structure of an optical waveguide device according to the related art. As shown in FIG. 1, the optical waveguide device of the related art can be used in an AR display apparatus. The optical waveguide device of the related art includes an optical waveguide plate 11, and an in-coupling grating 12, a turning grating 13, and an out-coupling grating 14 that are provided on the optical waveguide plate 11. The in-coupling grating 12, the turning grating 13, and the out-coupling grating 14 all adopt one-dimensional gratings, the turning grating 13 is located on one side of the out-coupling grating 14 in a first direction D1, and the in-coupling grating 12 is located on one side of the turning grating 13 in an opposite direction of a second direction D2. Orthographic projections of the in-coupling grating 12 and the out-coupling grating 14 on the optical waveguide plate 11 are both rectangular, and an orthographic projection of the turning grating 13 on the optical waveguide plate 11 are trapezoidal. An area of an orthographic projection of the in-coupling grating 12 on the optical waveguide plate 11 is much smaller than an area of an orthographic projection of the turning grating 13 on the optical waveguide plate 11. The turning grating 13 is configured to perform one-dimensional pupil expansion of the totally reflected light in the optical waveguide plate 11, and divide the field of view angle. Generally, it propagates the left field of view angle and the right field of view angle in two directions to increase the field of view angle.

Through the research of the inventors of the present disclosure, it is found that the optical waveguide device of the above related art can only utilize optical in-coupling at a certain order, which wastes a large amount of optical energy. One-dimensional turning grating needs to occupy a relatively large area in the waveguide sheet to achieve pupil expansion in one direction, thus reducing the degree of freedom in the design of the out-coupling grating area, especially for the future design of larger field of view (FOV) and larger Eye box.

An embodiment of the present disclosure provides an optical waveguide device for an AR display apparatus, the optical waveguide device including: an optical waveguide plate, and an in-coupling grating, at least two turning gratings and an out-coupling grating that are provided on the optical waveguide plate. The in-coupling grating is configured to in-couple incident light into the optical waveguide plate and to form +1-order diffracted light and −1-order diffracted light in the optical waveguide plate.

The at least two turning gratings include a first turning grating and a second turning grating, and the first turning grating is configured to receive the +1-order diffracted light from the optical waveguide plate and to propagate the +1-order diffracted light toward the out-coupling grating. The second turning grating is configured to receive the −1-order diffracted light from the optical waveguide plate and to propagate the −1-order diffracted light toward the out-coupling grating.

The out-coupling grating is configured to receive +1-order diffracted light from the first turning grating and −1-order diffracted light from the second turning grating and to emit the +1-order diffracted light and the −1-order diffracted light.

In an exemplary implementation, the first turning grating, the second turning grating, and the in-coupling grating are all located on one side of the out-coupling grating in a first direction, and the first turning grating and the second turning grating are located on two opposite sides of the in-coupling grating in a second direction. The first direction intersects the second direction, and the first direction and the second direction are both parallel to the optical waveguide plate.

In an exemplary implementation, a ratio of a sum of areas of orthographic projections of the at least two turning gratings on the optical waveguide plate to an area of an orthographic projection of the out-coupling grating on the optical waveguide plate is from 1:10 to 2:1.

In an exemplary implementation, the in-coupling grating forms the +1-order diffracted light and the −1-order diffracted light with the same diffraction efficiency.

The solution of the present embodiment will be illustrated below through some examples.

FIG. 2 is a first schematic diagram of a structure of an optical waveguide device according to an embodiment of the present disclosure. As shown in FIG. 2, an optical waveguide device according to an embodiment of the present disclosure can be used in an AR display apparatus, the optical waveguide device including: an optical waveguide plate 21, and one in-coupling grating 22, at least two turning gratings 23, and one out-coupling grating 24 that are provided on the optical waveguide plate 21. The in-coupling grating 22 is configured to in-couple incident light into the optical waveguide plate 21 in which +1-order diffracted light propagating in the second direction D2 and −1-order diffracted light propagating in the opposite direction of the second direction D2 are formed. The at least two turning gratings 23 include a first turning grating 231 and a second turning grating 232. The first turning grating 231 is configured to receive the +1-order diffracted light from the optical waveguide plate 21 and to propagate the +1-order diffracted light toward the out-coupling grating 24. The second turning grating 232 is configured to receive the −1-order diffracted light from the optical waveguide plate 21 and propagate the −1-order diffracted light toward the out-coupling grating 24. The out-coupling grating 24 is configured to receive +1-order diffracted light from the first turning grating 231 and −1-order diffracted light from the second turning grating 232 and to emit the +1-order diffracted light and the −1-order diffracted light.

The optical waveguide device of the embodiment of the present disclosure propagates the +1-order diffracted light and the −1-order diffracted light in the optical waveguide plate 21 toward the out-coupling grating 24 through the first turning grating 231 and the second turning grating 232, thereby realizing full utilization of optical energy. In the optical waveguide device of the embodiment of the present disclosure, the first turning grating 231 and the second turning grating 232 are used to change the propagation direction of the +1-order diffracted light and the −1-order diffracted light, and the area of orthographic projections of the first turning grating 231 and the second turning grating 232 on the optical waveguide plate 21 can be reduced, thereby increasing the area of the orthographic projection of the out-coupling grating 24 on the optical waveguide plate 21. Consequently, the area of the out-coupling grating 24 can be maximized, improving the freedom of optical design.

In an exemplary implementation, a ratio of a sum of the areas of orthographic projections of the at least two turning gratings on the optical waveguide plate to an area of an orthographic projection of the out-coupling grating on the optical waveguide plate is from 1:10 to 2:1.

In an exemplary implementation, as shown in FIG. 2, the in-coupling grating 22, the first turning grating 231, and the second turning grating 232 are all one-dimensional gratings, and the out-coupling grating 24 is a two-dimensional grating. The out-coupling grating 24 is further configured to perform two-dimensional pupil expansion of the +1-order diffracted light from the first turning grating 231 and the −1-order diffracted light from the second turning grating 232 to increase the field of view angle.

In an exemplary implementation, as shown in FIG. 2, the first turning grating 231, the second turning grating 232, and the in-coupling grating 22 are all located on one side of the out-coupling grating 24 in the first direction D1, and the first turning grating 231 and the second turning grating 232 are located on two opposite sides of the in-coupling grating 22 in the second direction D2. In this way, the first turning grating 231 can receive the +1-order diffracted light formed in the optical waveguide plate 21 by the in-coupling grating 22 and propagated in the second direction D2, and the second turning grating 232 can receive the −1-order diffracted light formed in the optical waveguide plate 21 by the in-coupling grating 22 and propagated in the opposite direction of the second direction D2. The first direction D1 intersects the second direction D2, and both the first direction D1 and the second direction D2 are parallel to the optical waveguide plate 21. For example, the first direction D1 is perpendicular to the second direction D2.

In the exemplary implementation, as shown in FIG. 2, the shapes of the orthographic projections of the in-coupling grating 22 and the out-coupling grating 24 on the optical waveguide plate 21 are both rectangular, the shapes of the orthographic projections of the first turning grating 231 and the second turning grating 232 on the optical waveguide plate 21 are trapezoidal, and the long base of the first turning grating 231 is located on one side of the short base of the first turning grating 231 in the second direction. The long base of the second turning grating 232 is located on one side of the short base of the first turning grating 231 in the opposite direction of the second direction. The areas of the orthographic projections of the in-coupling grating 22, the first turning grating 231, and the second turning grating 232 on the optical waveguide plate 21 are much smaller than the area of the orthographic projection of the out-coupling grating 24 on the optical waveguide plate 21.

In an exemplary implementation, as shown in FIG. 2, the optical waveguide plate 21 may be made of a transparent material, and the optical waveguide plate 21 can enable the light in-coupled by the in-coupling grating 22 to undergo total reflection transmission in the optical waveguide plate 21, thereby improving the optical energy utilization efficiency of the optical waveguide device.

In an exemplary implementation, as shown in FIG. 2, the optical waveguide plate 21 has a first surface, and the first surface may be a flat surface. The in-coupling grating 22, the at least two turning gratings 23 and the out-coupling grating 24 are all provided on the first surface of the optical waveguide plate 21. The optical waveguide plate 21 provides an installation position for the in-coupling grating 22, the at least two turning gratings 23 and the out-coupling grating 24, improving the reliability of the use of the in-coupling grating 22, the at least two turning gratings 23 and the out-coupling grating 24. At the same time, it ensures the uniformity of light transmission in the optical waveguide plate 21, and ensures that the optical waveguide device can uniformly image. By providing the in-coupling grating 22 on the first surface of the optical waveguide plate 21, the in-coupling grating 22 can in-couple most of the external light into the optical waveguide plate 21, thereby ensuring the in-coupling efficiency of the optical waveguide plate 21.

In an exemplary implementation, the material of the optical waveguide plate 21 includes a polymer or an inorganic material, such as glass. The material of the optical waveguide plate 21 has a refractive index of 1.5 to 2.2.

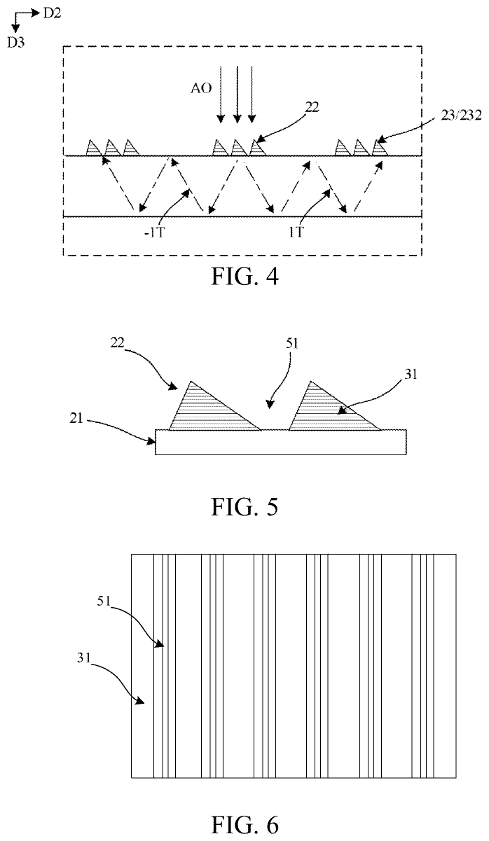

FIG. 3 is a schematic diagram of a planar structure of optical path propagation of an optical waveguide device according to an embodiment of the present disclosure. FIG. 4 is a schematic diagram of a cross-sectional structure of optical path propagation of an optical waveguide device according to an embodiment of the present disclosure. FIG. 4 may be a schematic diagram of a cross-sectional structure at a in FIG. 3. In the exemplary implementation, as shown in FIGS. 3 and 4, as an example, the +1-order diffracted light is considered as a 1T-order diffracted light and the −1-order diffracted light is considered as a −1T-order diffracted light. The optical path propagation process of the optical waveguide device according to the embodiment of the present disclosure is as follows. The incident light AO is incident on the in-coupling grating 22 along a direction perpendicular to the optical waveguide plate 21. The in-coupling grating 22 in-couples the incident light AO into the optical waveguide plate 21, and total reflection occurs in the optical waveguide plate 21 to form 1T-order diffracted light (positive first order diffracted light) and −1T-order diffracted light (negative first order diffracted light). The 1T-order diffracted light propagates along the second direction D2 and the −1-order diffracted light propagates along a opposite direction of the second direction D2. The 1T-order diffracted light propagates in the optical waveguide plate 21 to the first turning grating 231, and the first turning grating 231 changes the propagation direction of the 1T-order diffracted light, diffracts the 1T-order diffracted light in the opposite direction of the first direction D1, and causes the 1T-order diffracted light to form 1R-order diffracted light propagating toward the out-coupling grating 24. The −1T-order diffracted light propagate in the optical waveguide plate 21 to the second turning grating 232, and the second turning grating 232 changes the propagation direction of the −1T-order diffracted light, diffracts the −1T-order diffracted light toward the first direction D1, and causes the −1T-order diffracted light to form −1R-order diffracted light propagating toward the out-coupling grating 24. The 1R-order diffracted light and the −1R-order diffracted light propagate to the out-coupling grating 24, and the out-coupling grating 24 performs two-dimensional pupil expansion of the 1R-order diffracted light and the −1R-order diffracted light. That is, the out-coupling grating 24 performs pupil expansion of the 1R-order diffracted light and the −1R-order diffracted light in the first direction D1 and the second direction D2, and emits the 1R-order diffracted light and the −1R-order diffracted light.

In an exemplary implementation, the diffraction efficiency of the in-coupling grating 22 for forming the +1-order diffracted light in the optical waveguide plate 21 is substantially the same as the diffraction efficiency of the in-coupling grating 22 for forming the −1-order diffracted light in the optical waveguide plate 21. This improves the brightness uniformity of the optical waveguide device and reduces the difficulty of preparing the subsequent turning grating and the out-coupling grating.

In an exemplary implementation, the first turning grating 231 has a high diffraction efficiency for forming the 1R-order diffracted light from the 1T-order diffracted light. For example, the diffraction efficiency of the first turning grating 231 for forming the 1R-order diffracted light from the 1T-order diffracted light is from 60% to 100%, so that the number of times the 1T-order diffracted light is transmitted along the second direction D2 (0R) by the first turning grating 231 can be reduced.

In an exemplary implementation, the second turning grating 232 has high diffraction efficiency for forming the −1R-order diffracted light from the −1T-order diffracted light. For example, the diffraction efficiency of the second turning grating 232 for forming the −1R-order diffracted light from the −1T-order diffracted light is from 60% to 100%, so that the number of times the −1T-order diffracted light is transmitted along the opposite direction of the second direction D2 (−0R) by the second turning grating 232 can be reduced.

The optical waveguide device according to the embodiment of the present disclosure has high diffraction efficiency for 1T-order diffracted light and −1T-order diffracted light through the first turning grating 231 and the second turning grating 232, ensuring that 1T-order diffracted light and −1T-order diffracted light may be turned into the out-coupling grating 24 by light transmission within several times.

FIG. 5 is a first schematic diagram of a cross-sectional structure of an in-coupling grating in an optical waveguide device according to an embodiment of the present disclosure. FIG. 6 is a schematic diagram of a planar structure of an in-coupling grating in an optical waveguide device according to an embodiment of the present disclosure. Herein, FIG. 6 is a schematic diagram of the planar structure of the in-coupling grating in FIG. 5. In an exemplary implementation, as shown in FIGS. 5 and 6, the in-coupling grating 22 is a one-dimensional grating, and the in-coupling grating 22 is a blazed grating. The in-coupling grating 22 includes a plurality of first grating structures 31 that are periodically arranged, and a first slit 51 is formed between adjacent first grating structures 31. In a plane parallel to the optical waveguide plate 21, the first grating structure 31 is in a shape of an elongated strip. In a plane perpendicular to the optical waveguide plate 21, a cross section of the first grating structure 31 is triangular, and an internal angle of the first grating structure 31 is from 30 degrees to 90 degrees. In some embodiments, the in-coupling grating may also be a tilted grating or a rectangular grating.

In the optical waveguide device of the embodiment of the present disclosure, the in-coupling grating 22 is a blazed grating or a tilted grating, and has higher 1-order diffraction efficiency than a rectangular grating. Rectangular gratings belong to amplitude gratings, and phases of 0-order in single-slit diffraction and 0-order in multi-slit interference coincide, resulting in ±1-order diffraction light efficiency always being less than 0-order diffraction light efficiency. For blazed grating, due to the existence of blaze angle, the 0-order in single-slit diffraction and the 0-order in multi-slit interference can be separated in phase, and the 0-order in single-slit diffraction falls on the ±1-order in multi-slit interference, so that the ±1-order diffraction efficiency is higher than the 0-order diffraction efficiency. At the same time, after optimizing the grating parameters, the ±1-order diffraction efficiency can be approximately consistent. After a large number of simulations, the blazed grating is more likely to meet the condition that the diffraction efficiencies of the +1-order diffraction order and the −1-order diffraction order are close, so the in-coupling grating 22 in the optical waveguide device of the embodiment of the present disclosure is preferably a blazed grating.

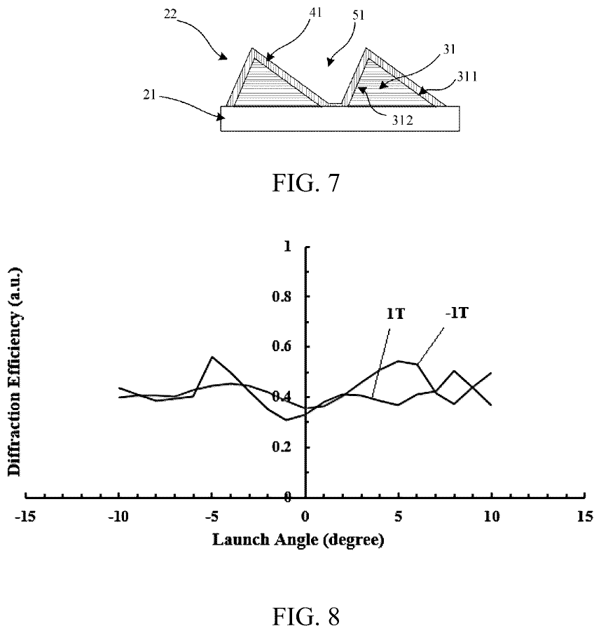

FIG. 7 is a second schematic diagram of a cross-sectional structure of an in-coupling grating in an optical waveguide device according to an embodiment of the present disclosure. In an exemplary implementation, as shown in FIG. 7, the in-coupling grating 22 is a blazed grating, and the first grating structure 31 of the in-coupling grating 22 includes a first side surface 311 and a second side surface 312, both of which form an acute angle with the surface of the optical waveguide plate 21. For example, the first side surface 311 and the second side surface 312 form an included angle of 30 degrees to 90 degrees with the surface of the optical waveguide plate 21. A transparent dielectric layer 41 is provided on the surface of the first grating structure 31, and the transparent dielectric layer 41 covers the first side surface 311 and the second side surface 312 of the first grating structure 31. The refractive index of the transparent dielectric layer 41 is different from the refractive index of the first grating structure 31, and the transparent dielectric layer 41 can improve the diffraction efficiency of the in-coupling grating 22.

FIG. 8 is a simulation graph of an in-coupling grating in an optical waveguide device according to an embodiment of the present disclosure. And the abscissa in FIG. 8 is the launch angle of 1T-order diffracted light and −1T-order diffracted light. The ordinate in FIG. 8 is the diffraction efficiency of light. FIG. 8 is a simulation graph of the in-coupling grating 22 shown in FIG. 7. Through the research of the inventors of the present disclosure, it is found that providing the transparent dielectric layer 41 on the in-coupling grating 22 can increase the degree of freedom of design and improve the diffraction efficiency of the in-coupling grating 22. As shown in FIG. 8, both the 1T-order diffracted light and the −1T-order diffracted light have an average diffraction efficiency of 40%, and the total diffraction efficiency (the sum of the diffraction efficiencies of the 1T-order diffracted light and the −1T-order diffracted light) of the in-coupling grating in the optical waveguide device according to the embodiment of the present disclosure is not less than 80%. Compared with the conventional optical waveguide device, which has a maximum diffraction efficiency of 50%, the optical waveguide device according to the embodiment of the present disclosure can greatly improve the light efficiency. It should be noted that the simulation result is not an optimal solution, but only illustrates the feasibility of the present invention.

In an exemplary implementation, a material of the first grating structure 31 has a refractive index of 1.5 to 2.2. A material of the transparent dielectric layer 41 has a refractive index of 1.5 to 3.0.

In an exemplary implementation, the material of the first grating structure 31 includes a polymer or an inorganic material, for example, glass.

In an exemplary implementation, the material of the transparent dielectric layer 41 is an inorganic material, for example, titanium dioxide, silicon nitride, or the like.

In an exemplary implementation, a period of the in-coupling grating 22 is from 250 nanometers to 450 nanometers; and/or the in-coupling grating 22 has a duty cycle of 0.2 to 0.8; and/or a height of the first grating structure 31 of the in-coupling grating 22 is from 50 nanometers to 500 nanometers. And one first grating structure 31 and one first slit 51 adjacent thereto are connected to form one period of the in-coupling grating 22. One period of the in-coupling grating 22 has a width d, a width of the first grating structure is a, a width of the first slit 51 is b, and a duty cycle of the in-coupling grating 22 is a/d.

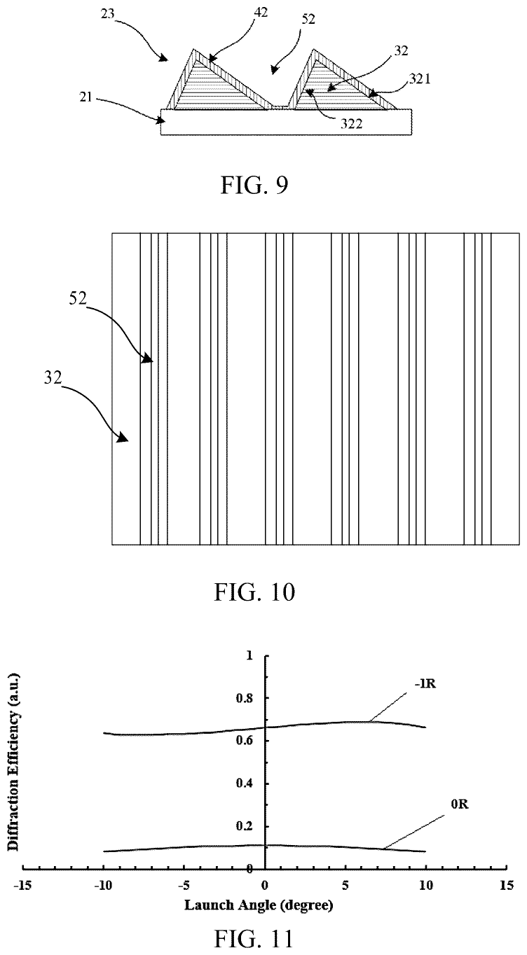

FIG. 9 is a schematic diagram of a cross-sectional structure of a turning grating in an optical waveguide device according to an embodiment of the present disclosure. FIG. 10 is a schematic diagram of a planar structure of a turning grating in an optical waveguide device according to an embodiment of the present disclosure. And FIG. 10 is a schematic diagram of the planar structure of the turning grating in FIG. 9. In an exemplary implementation, as shown in FIGS. 9 and 10, the turning grating 23 is a one-dimensional grating, and the turning grating 23 is a blazed grating. The turning grating 23 includes a plurality of second grating structures 32 that are periodically arranged, and a second slit 52 is formed between adjacent second grating structures 32. In a plane parallel to the optical waveguide plate 21, the second grating structure 32 is in a shape of an elongated strip. In a plane perpendicular to the optical waveguide plate 21, a cross section of the second grating structure 32 is triangular. An internal angle of the first grating structure 31 is from 30 degrees to 90 degrees. In some embodiments, the turning grating may also be a tilted grating or a rectangular grating.

In the optical waveguide device of the embodiment of the present disclosure, the turning grating 23 is a blazed grating or a tilted grating, and has higher 1-order diffraction efficiency than a rectangular grating.

In an exemplary implementation, as shown in FIG. 9, the turning grating 23 is a blazed grating, and the second grating structure 32 of the turning grating 23 includes a third side surface 321 and a fourth side surface 322, both of which form an acute angle with the surface of the optical waveguide plate 21. For example, the third side surface 321 and the fourth side surface 322 form an included angle of 30 degrees to 90 degrees with the surface of the optical waveguide plate 21. A reflective layer 42 is provided on the surface of the second grating structure 32, and the reflective layer 42 covers the third side surface 321 and the fourth side surface 322 of the second grating structure 32. The refractive index of the reflective layer 42 is different from the refractive index of the second grating structure 32, and the reflective layer 42 can improve the diffraction efficiency of the turning grating 23 for the +1-order diffracted light and the −1-order diffracted light.

FIG. 11 is a simulation graph of a turning grating in an optical waveguide device according to an embodiment of the present disclosure. And the abscissa in FIG. 11 is the launch angle of 0R-order diffracted light and −1R-order diffracted light. The ordinate in FIG. 11 is the diffraction efficiency of light. FIG. 11 is a simulation graph of the turning grating 23 shown in FIG. 9. Through the research of the inventors of the present disclosure, it is found that providing the reflective layer 42 on the turning grating 23 can increase the degree of freedom of design and improve the diffraction efficiency of the turning grating 23. As shown in FIG. 11, the turning grating 23 has a high diffraction efficiency for −1T-order diffracted light, so that most of the −1T-order diffracted light can be formed into −1R-order diffracted light in only 2 to 3 times, and the −1T-order diffracted light can be turned into the in-coupling grating. It should be noted that the simulation result is not an optimal solution, but only illustrates the feasibility of the present invention.

In an exemplary implementation, the turning grating 23 has a step size of 2Ttanα for each light transmission, and the turning grating 23 has a step size of 1 mm to 2 mm for each light transmission. This design reduces the area of the turning grating 23 in the region where the optical waveguide plate 21 is located, so that the area of the turning grating 23 in the region where the optical waveguide plate 21 is located is only square millimeters.

In an exemplary implementation, a material of the second grating structure 32 has a refractive index of 1.5 to 2.2. A material of the reflective layer 42 has a refractive index of 1.5 to 3.0.

In an exemplary implementation, the material of the second grating structure 32 includes a polymer or an inorganic material, for example, glass.

In an exemplary implementation, the material of the reflective layer 42 is a metal or an alloy, for example, the material of the reflective layer 42 is at least one of aluminum and an alloy thereof, silver and an alloy thereof.

In an exemplary implementation, a period of the turning grating 23 is from 250 nanometers to 450 nanometers; and/or the turning grating 23 has a duty cycle of 0.2 to 0.8; and/or a height of the second grating structure 32 of the turning grating 23 is from 50 nanometers to 500 nanometers.

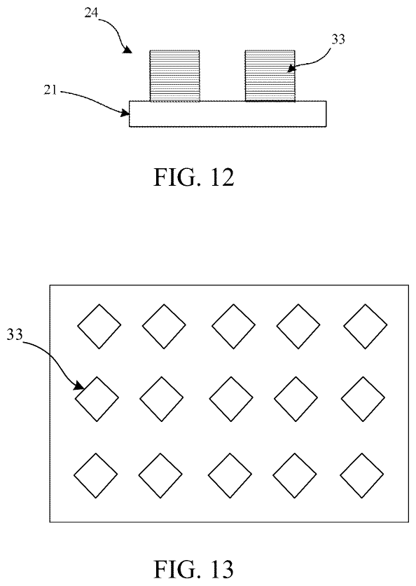

FIG. 12 is a first schematic diagram of a cross-sectional structure of an out-coupling grating in an optical waveguide device according to an embodiment of the present disclosure. FIG. 13 is a schematic diagram of a planar structure of an out-coupling grating in an optical waveguide device according to an embodiment of the present disclosure. And FIG. 13 is a schematic diagram of the planar structure of the out-coupling grating in FIG. 12. In an exemplary implementation, as shown in FIGS. 12 and 13, the out-coupling grating 24 is a two-dimensional grating. The out-coupling grating 24 is a blazed grating. The out-coupling grating 24 includes a plurality of third grating structures 33 that are periodically arranged, and the third grating structure 33 is in a cylinder shape. In a plane parallel to the optical waveguide plate 21, an orthographic projection of the third grating structure 33 on the optical waveguide plate 21 is diamond-shaped. In a plane perpendicular to the optical waveguide plate 21, the cross section of the third grating structure 33 is triangular.

In some embodiments, the orthographic projection of the third grating structure on the optical waveguide plate may further include at least one of circle, triangle, parallelogram, and rectangle.

In an exemplary implementation, a central axis of the third grating structure 33 is perpendicular to the optical waveguide plate 21.

In an exemplary implementation, the area of the orthographic projection of the out-coupling grating 24 on the optical waveguide plate 21 is greater than or equal to 20 square millimeters, thereby improving the light emission efficiency.

In an exemplary implementation, a material of the third grating structure 33 has a refractive index of 1.5 to 2.2. A material of the reflective layer 42 has a refractive index of 1.5 to 3.0.

In an exemplary implementation, the material of the third grating structure 33 includes a polymer or an inorganic material, for example, glass.

In an exemplary implementation, a period of the out-coupling grating 24 is from 250 nanometers to 450 nanometers; and/or the out-coupling grating 24 has a duty cycle of 0.1 to 0.9; and/or a height of the third grating structure 33 of the out-coupling grating 24 is from 50 nanometers to 500 nanometers.

In an exemplary implementation, at least some of the third grating structures of the out-coupling grating may have different shapes, thereby improving the uniformity of luminance of emitting light from the out-coupling grating.

In an exemplary implementation, at least some of the third grating structures of the out-coupling grating may have different sizes, thereby improving the uniformity of luminance of emitting light from the out-coupling grating. For example, at least some of the third grating structures of the out-coupling grating gradually get bigger or smaller along a direction parallel to the optical waveguide plate.

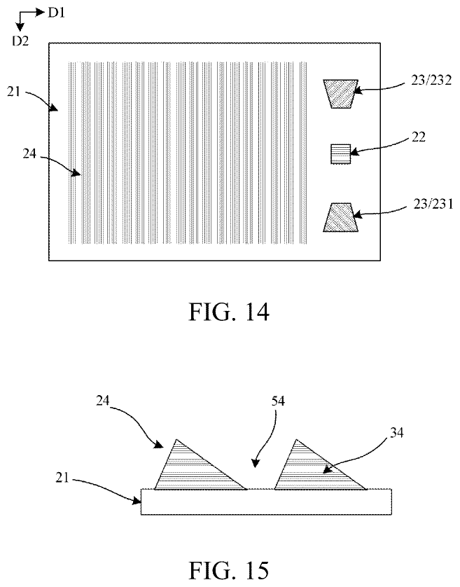

FIG. 14 is a first schematic diagram of a structure of an optical waveguide device according to an embodiment of the present disclosure. FIG. 15 is a second schematic diagram of a cross-sectional structure of an out-coupling grating in an optical waveguide device according to an embodiment of the present disclosure. In an exemplary implementation, as shown in FIGS. 14 and 15, the structure of the optical waveguide device of the embodiment of the present disclosure is substantially the same as that of the optical waveguide device shown in FIG. 2, except that the out-coupling grating 24 is a one-dimensional grating. The out-coupling grating 24 includes a plurality of fourth grating structures 34 that are periodically arranged, and a fourth slit 54 is formed between adjacent fourth grating structures 34. In a plane parallel to the optical waveguide plate 21, the fourth grating structure 34 is in a shape of an elongated strip. In a plane perpendicular to the optical waveguide plate 21, the cross section of the fourth grating structure 34 is triangular.

In an exemplary implementation, the out-coupling grating 24 includes at least one of a blazed grating, a tilted grating, and a rectangular grating.

In an exemplary implementation, a material of the fourth grating structure 34 has a refractive index of 1.5 to 2.2. A material of the reflective layer 42 has a refractive index of 1.5 to 3.0.

In an exemplary implementation, the material of the fourth grating structure 34 includes a polymer or an inorganic material, for example, glass.

In an exemplary implementation, in a plane perpendicular to the optical waveguide plate 21, a cross section of the fourth grating structure 34 is triangular, and an internal angle of the fourth grating structure 34 is from 30 degrees to 90 degrees.

In an exemplary implementation, a period of the out-coupling grating 24 is from 250 nanometers to 450 nanometers; and/or the out-coupling grating 24 has a duty cycle of 0.2 to 0.8; and/or a height of the fourth grating structure 34 of the out-coupling grating 24 is from 50 nanometers to 500 nanometers.

In an exemplary implementation, the first turning grating 231 is further configured to perform pupil expansion of the +1-order diffracted light in a third direction; and/or the second turning grating 232 is further configured to perform pupil expansion of the −1-order diffracted light in the third direction. The out-coupling grating 24 is further configured to perform pupil expansion of the pupil of the received +1-order diffracted light and the received −1-order diffracted light in a fourth direction, so that the +1-order diffracted light and the −1-order diffracted light achieve two-dimensional pupil expansion through the turning grating 23 and the out-coupling grating 24, increasing the field of view angle. Here, the third direction intersects the fourth direction, the third direction may be the second direction D2, and the fourth direction may be the first direction D1.

An embodiment of the present disclosure further provides an AR display apparatus, including the optical waveguide device described in any one of above embodiments.

An embodiment of the present disclosure also provides a preparation method of an optical waveguide device, and the optical waveguide device may be the optical waveguide device described in any one of above embodiments. The preparation method of the optical waveguide device uses a nanoimprinting process to form a grating structure of an in-coupling grating, a turning grating and an out-coupling grating.

A preparation method of an optical waveguide device according to an embodiment of the present disclosure includes: providing an optical waveguide plate; and forming an in-coupling grating, at least two turning gratings and an out-coupling grating on the optical waveguide plate. The in-coupling grating is configured to in-couple incident light into the light waveguide plate and to form +1-order diffracted light and −1-order diffracted light in the light waveguide plate. The at least two turning gratings include a first turning grating and a second turning grating, the first turning grating is configured to receive the +1-order diffracted light from the optical waveguide plate and to propagate the +1-order diffracted light toward the out-coupling grating. The second turning grating is configured to receive the −1-order diffracted light from the optical waveguide plate and to propagate the −1-order diffracted light toward the out-coupling grating. The out-coupling grating is configured to receive the +1-order diffracted light from the first turning grating and the −1-order diffracted light from the second turning grating and to emit the +1-order diffracted light and the −1-order diffracted light.

In an exemplary implementation, in the preparation method of the optical waveguide device of the embodiment of the present disclosure, a nanoimprinting process may be used to form an in-coupling grating, at least two turning gratings, and an out-coupling grating.

In an exemplary implementation, forming an in-coupling grating, at least two turning gratings, and an out-coupling grating by using a nanoimprinting process, including: forming an imprinting adhesive layer on the optical waveguide plate; imprinting the imprinting adhesive layer with a mother template having an in-coupling grating pattern, a turning grating pattern and an out-coupling grating pattern by using a nanoimprinting process, so that the imprinting adhesive layer forms a first grating structure, a second grating structure and a third grating structure; and forming the first grating structure into an in-coupling grating, forming the second grating structure into a turning grating, and forming the third grating structure into an out-coupling grating.

In an exemplary implementation, a transparent dielectric layer may be formed on the first grating structure such that the first grating structure and the transparent dielectric layer form an in-coupling grating; and/or a reflective layer may be formed on the second grating structure, such that the second grating structure and the reflective layer form a turning grating. The transparent dielectric layer can be made of an inorganic material and the reflective layer can be made of a metal or alloy.

In an exemplary implementation, an imprinting adhesive layer can be imprinted with a mother template having an in-coupling grating pattern, a turning grating pattern and an out-coupling grating pattern by using a nanoimprinting process, so that the imprinting adhesive layer forms a first grating structure pattern, a second grating structure pattern and a third grating structure pattern.

Subsequently, the imprinting adhesive layer and the optical waveguide plate are etched, the first grating structure pattern, the second grating structure pattern and the third grating structure pattern of the imprinting adhesive layer are formed on the optical waveguide plate, and the first grating structure, the second grating structure and the third grating structure are formed by partial etching of the optical waveguide plate. The first grating structure, the second grating structure, and the third grating structure are made of the same material as the optical waveguide plate, and the first grating structure, the second grating structure, and the third grating structure form an integrated structure with the optical waveguide plate.

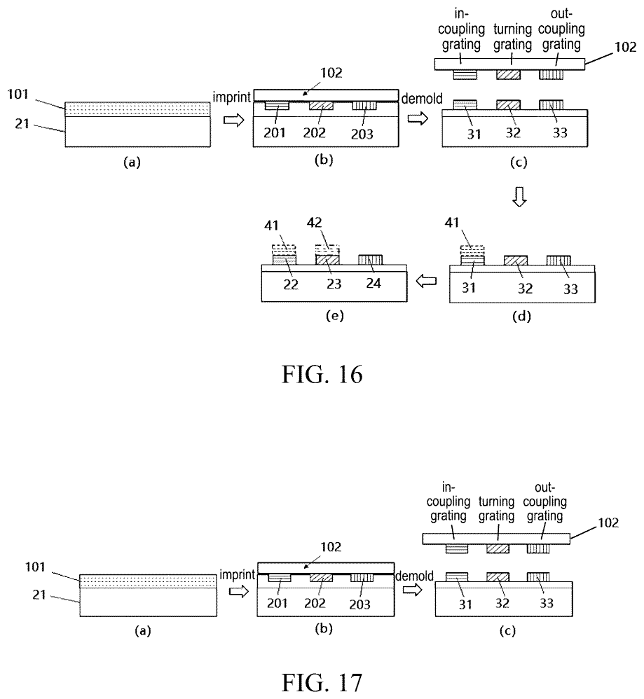

FIG. 16 is a first schematic diagram of a preparation process of an optical waveguide device according to an embodiment of the present disclosure. The optical waveguide device includes an optical waveguide plate, and an in-coupling grating, a turning grating and an out-coupling grating that are provided on the optical waveguide plate. The in-coupling grating and the turning grating are one-dimensional gratings, and the out-coupling grating is a two-dimensional grating. The in-coupling grating includes a plurality of first grating structures in a shape of an elongated strip that are periodically arranged, a transparent dielectric layer is provided on the surface of the first grating structure, a refractive index of the transparent dielectric layer is different from that of the first grating structure, and a material of the transparent dielectric layer is an inorganic material, for example, titanium dioxide, silicon nitride, etc. The turning grating includes a plurality of second grating structures in a shape of an elongated strip that are periodically arranged, a reflective layer is provided on a surface of the second grating structure, a refractive index of the reflective layer is different from that of the second grating structure, and a material of the reflective layer is metal. The out-coupling grating includes a plurality of third grating structures that are periodically arranged, and the third grating structure is in a cylinder shape.

The preparation method of the optical waveguide device includes the following steps.

S101: forming an imprinting adhesive layer.

Forming the imprinting adhesive layer includes: first providing an optical waveguide plate 21, depositing an imprinting adhesive thin film on the optical waveguide plate 21, and performing a patterning process so that the imprinting adhesive thin film forms an imprinting adhesive layer 101 provided on a surface on a side of the optical waveguide plate 21, as shown in (a) of FIG. 16.

S102: performing nanoimprinting.

Performing nanoimprinting includes: providing a mother template 102 on the optical waveguide plate 21 on which the aforementioned pattern is formed, a surface on a side of the mother template 102 being provided with an in-coupling grating pattern 201, a turning grating pattern 202, and an out-coupling grating pattern 203; subsequently, nanoimprinting the imprinting adhesive layer 101 with the side of the mother template 102 having the in-coupling grating pattern 201, the turning grating pattern 202, and the out-coupling grating pattern 203, as shown in (b) of FIG. 16.

S103: forming a first grating structure, a second grating structure, and a third grating structure.

Forming a first grating structure, a second grating structure, and a third grating structure includes: demolding the mother template 102 from the imprinting adhesive layer 101 on the optical waveguide plate 21 on which the aforementioned pattern is formed, to form the first grating structure 31, the second grating structure 32, and the third grating structure 33 provided on the optical waveguide plate 21, as shown in (c) of FIG. 16. The third grating structure 33 forms the out-coupling grating 24.

S104: forming an in-coupling grating.

Forming an in-coupling grating includes: forming a transparent dielectric layer 41 on the first grating structure 31 on the optical waveguide plate 21 on which the aforementioned pattern is formed, the first grating structure 31 and the transparent dielectric layer 41 forming the in-coupling grating 22, as shown in (d) of FIG. 16. The transparent dielectric layer 41 is made of an inorganic material.

S105: forming a turning grating.

Forming a turning grating includes: forming a reflective layer 42 on the second grating structure 32 on the optical waveguide plate 21 on which the aforementioned pattern is formed, the second grating structure 32 and the reflective layer 42 forming the turning grating 23, as shown in (e) of FIG. 16. The reflective layer 42 is made of a metal.

FIG. 17 is a second schematic diagram of a preparation process of an optical waveguide device according to an embodiment of the present disclosure. The optical waveguide device includes an optical waveguide plate, and an in-coupling grating, a turning grating and an out-coupling grating that are provided on the optical waveguide plate. The in-coupling grating and the turning grating are one-dimensional gratings, and the out-coupling grating is a two-dimensional grating. The in-coupling grating includes a plurality of first grating structures in a shape of an elongated strip that are periodically arranged. The turning grating includes a plurality of second grating structures in a shape of an elongated strip that are periodically arranged. The out-coupling grating includes a plurality of third grating structures that are periodically arranged, and the third grating structure is in a cylinder shape.

The preparation method of the optical waveguide device includes the following steps.

S201: forming an imprinting adhesive layer.

Forming an imprinting adhesive layer includes: first providing an optical waveguide plate 21, depositing an imprinting adhesive thin film on the optical waveguide plate 21, and performing a patterning process so that the imprinting adhesive thin film forms an imprinting adhesive layer 101 provided on a surface on a side of the optical waveguide plate 21, as shown in (a) of FIG. 17.

S202: performing nanoimprinting.

Performing nanoimprinting includes: providing a mother template 102 on the optical waveguide plate 21 on which the aforementioned pattern is formed, a surface on a side of the mother template 102 being provided with an in-coupling grating pattern 201, a turning grating pattern 202, and an out-coupling grating pattern 203; subsequently, nanoimprinting the imprinting adhesive layer 101 with the side of the mother template 102 having the in-coupling grating pattern 201, the turning grating pattern 202, and the out-coupling grating pattern 203, as shown in (b) of FIG. 17.

S203, Forming an in-coupling grating, a turning grating, and an out-coupling grating.

Forming an in-coupling grating, a turning grating, and an out-coupling grating includes: demolding the mother template 102 from the imprinting adhesive layer 101 on the optical waveguide plate 21 on which the aforementioned pattern is formed, to form the first grating structure 31, the second grating structure 32, and the third grating structure 33 provided on the optical waveguide plate 21, as shown in (c) of FIG. 17. The first grating structure 31 forms an in-coupling grating, the second grating structure 32 forms a turning grating, and the third grating structure 33 forms an out-coupling grating.

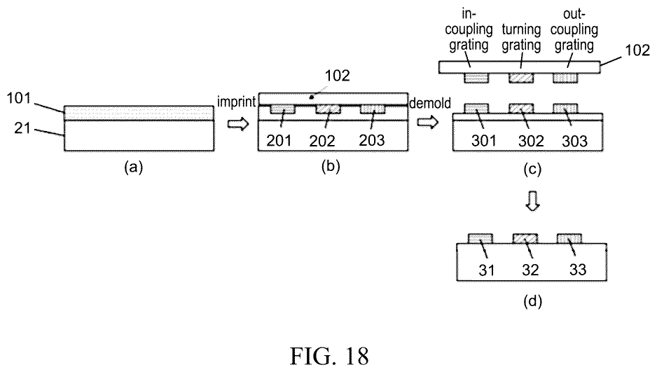

FIG. 18 is a third schematic diagram of a preparation process of an optical waveguide device according to an embodiment of the present disclosure. In an exemplary implementation, as shown in FIG. 18, the preparation process of the optical waveguide device is substantially the same as that of the optical waveguide device shown in FIG. 17, except that after step S202, in step S203, an in-coupling grating, a turning grating, and an out-coupling grating are formed.

Forming an in-coupling grating, a turning grating, and an out-coupling grating includes: demolding the mother template 102 from the imprinting adhesive layer 101 on the optical waveguide plate 21 on which the aforementioned pattern is formed, to form the first grating structure pattern 301, the second grating structure pattern 302, and the third grating structure pattern 303 on the imprinting adhesive layer 101, as shown in (c) of FIG. 18; subsequently, etching the imprinting adhesive layer 101 and the optical waveguide plate 21, replicating the first grating structure pattern, the second grating structure pattern and the third grating structure pattern of the imprinting adhesive layer 101 onto the optical waveguide plate 21, and forming a first grating structure 31, a second grating structure 32 and a third grating structure 33 by the partial etching of the optical waveguide plate 21. The first grating structure 31, the second grating structure 32 and the third grating structure 33 are made of the same materials as the optical waveguide plate 21, and the first grating structure 31, the second grating structure 32 and the third grating structure 33 form an integrated structure with the optical waveguide plate 21, as shown in FIG. 18 (d).

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. An optical waveguide device for an AR display apparatus, the optical waveguide device comprising:
an optical waveguide plate, and an in-coupling grating, at least two turning gratings and an out-coupling grating that are provided on the optical waveguide plate;
wherein the in-coupling grating is configured to in-couple incident light into the optical waveguide plate and to form +1-order diffracted light and −1-order diffracted light in the optical waveguide plate;
the at least two turning gratings comprise a first turning grating and a second turning grating, the first turning grating is configured to receive the +1-order diffracted light from the optical waveguide plate and to propagate the +1-order diffracted light toward the out-coupling grating; the second turning grating is configured to receive the −1-order diffracted light from the optical waveguide plate and to propagate the −1-order diffracted light toward the out-coupling grating; and
the out-coupling grating is configured to receive +1-order diffracted light from the first turning grating and −1-order diffracted light from the second turning grating and to emit the +1-order diffracted light and the −1-order diffracted light.

2. The optical waveguide device according to claim 1, wherein the first turning grating, the second turning grating, and the in-coupling grating are all located on one side of the out-coupling grating in a first direction, the first turning grating and the second turning grating are located on two opposite sides of the in-coupling grating in a second direction, the first direction intersects the second direction, and the first direction and the second direction are both parallel to the optical waveguide plate.

3. The optical waveguide device according to claim 1, wherein a ratio of a sum of areas of orthographic projections of the at least two turning gratings on the optical waveguide plate to an area of an orthographic projection of the out-coupling grating on the optical waveguide plate is from 1:10 to 2:1.

4. (canceled)

5. The optical waveguide device according to claim 1, wherein the in-coupling grating is a one-dimensional grating, the in-coupling grating comprises a plurality of first grating structures that are periodically arranged, and a first grating structure of the plurality of first grating structures is in a shape of an elongated strip; or
wherein a turning grating of the turning gratings is a one-dimensional grating, and the turning grating comprises a plurality of second grating structures that are periodically arranged, and a second grating structure of the plurality of second grating structures is in a shape of an elongated strip.

6. (canceled)

7. The optical waveguide device according to claim 5, wherein a transparent dielectric layer is provided on a surface of the first grating structure of the in-coupling grating, and the transparent dielectric layer has a different refractive index from the first grating structure; and
wherein a material of the first grating structure has a refractive index of 1.5 to 2.2, and a material of the transparent dielectric layer has a refractive index of 1.5 to 3.0.

8-10. (canceled)

11. The optical waveguide device according to claim 5, wherein a period of the in-coupling grating is from 250 nanometers to 450 nanometers; and/or the in-coupling grating has a duty cycle of 0.2 to 0.8; and/or a height of the first grating structure of the in-coupling grating is from 50 nanometers to 500 nanometers; or
wherein the in-coupling grating is a blazed grating, a cross section of the first grating structure of the in-coupling grating is triangular in a direction perpendicular to the optical waveguide plate, and an internal angle of the first grating structure is from 30 degrees to 90 degrees.

12-14. (canceled)

15. The optical waveguide device according to claim 5, wherein a reflective layer is provided on a surface of the second grating structure of the turning grating, and the reflective layer has a different refractive index from the second grating structure; and
wherein the reflective layer has a refractive index of 1.5 to 3.

16-17. (canceled)

18. The optical waveguide device according to claim 5, wherein a step size of light transmission of the turning grating is from 1 mm to 2 mm; or
wherein a material of the second grating structure has a refractive index of 1.5 to 2.2.

19-20. (canceled)

21. The optical waveguide device according to claim 5, wherein a period of the turning grating is from 150 nanometers to 450 nanometers; and/or the turning grating has a duty cycle of 0.2 to 0.8; and/or a height of the second grating structure of the turning grating is from 50 nanometers to 500 nanometers; or
wherein the turning grating is a blazed grating, a cross section of the second grating structure of the turning grating is triangular in a direction perpendicular to the optical waveguide plate, and an internal angle of the second grating structure is from 30 degrees to 90 degrees.

22. (canceled)

23. The optical waveguide device according to claim 1, wherein the out-coupling grating is a two-dimensional grating, and the out-coupling grating comprises a plurality of third grating structures that are periodically arranged, and a third grating structure of the plurality of third grating structures is in a cylinder shape.

24. The optical waveguide device according to claim 23, wherein an orthographic projection of the third grating structure on the optical waveguide plate comprises at least one of circle, triangle, rectangle, parallelogram, and diamond shape; or
wherein a material of the third grating structure has a refractive index of 1.5 to 2.2.

25. (canceled)

26. The optical waveguide device according to claim 23, wherein a period of the out-coupling grating is from 250 nanometers to 450 nanometers; and/or the out-coupling grating has a duty cycle of 0.1 to 0.9; and/or a height of the third grating structure of the out-coupling grating is from 50 nanometers to 500 nanometers.

27-28. (canceled)

29. The optical waveguide device according to claim 23, wherein at least some of the third grating structures of the out-coupling grating have different shapes; or
wherein at least some of the third grating structures of the out-coupling grating gradually get bigger along a direction parallel to the optical waveguide plate.

30-31. (canceled)

32. The optical waveguide device according to claim 1, wherein an area of an orthographic projection of the out-coupling grating on the optical waveguide plate is greater than or equal to 20 square millimeters.

33. The optical waveguide device according to claim 1, wherein the first turning grating is further configured to perform pupil expansion of the +1-order diffracted light in a third direction; and/or the second turning grating is further configured to perform pupil expansion of the −1-order diffracted light in the third direction.

34. The optical waveguide device according to claim 33, wherein the out-coupling grating is a one-dimensional grating, the out-coupling grating comprises a plurality of fourth grating structures that are periodically arranged, a fourth grating structure of the plurality of fourth grating structures is in a shape of an elongated strip, the out-coupling grating is further configured to perform pupil expansion of the +1-order diffracted light and the −1-order diffracted light received in a fourth direction, and the third direction intersects the fourth direction.

35. (canceled)

36. The optical waveguide device according to claim 34, wherein a material of the fourth grating structure has a refractive index of 1.5 to 2.2.

37. (canceled)

38. The optical waveguide device according to claim 34, wherein a period of the out-coupling grating is from 250 nanometers to 450 nanometers; and/or the out-coupling grating has a duty cycle of 0.2 to 0.8; and/or a height of the fourth grating structure of the out-coupling grating is from 50 nanometers to 500 nanometers; and
wherein the out-coupling grating is a blazed grating, a cross section of the fourth grating structure of the out-coupling grating is triangular in a direction perpendicular to the optical waveguide plate, and an internal angle of the fourth grating structure is from 30 degrees to 90 degrees.

39. (canceled)

40. The optical waveguide device according to claim 1, wherein at least one of the in-coupling grating, the at least two turning gratings, and the out-coupling grating is made of the same material as the optical waveguide plate, and forms an integral structure with the optical waveguide plate; or
wherein a material of the optical waveguide plate has a refractive index of 1.5 to 2.2.

41-42. (canceled)

43. An AR display apparatus, comprising the optical waveguide device according to claim 1.
